(19) United States
(12) Patent Application Publication
(10) Pub. No.: US 2014/0224531 A1
(43) Pub. Date: Aug. 14, 2014

(54) SOLDER MASK INK COMPRISING AMIDE GELLANT

(71) Applicant: XEROX CORPORATION, Norwalk, CT (US)

(72) Inventors: Naveen Chopra, Oakville (CA); Yiliang WU, Oakville (CA)

(73) Assignee: XEROX CORPORATION, Norwalk, CT (US)

(21) Appl. No.: 13/765,403

(22) Filed: Feb. 12, 2013

(51) Int. Cl. H01B 3/44; H05K 1/02

(52) U.S. Cl. CPC H01B 3/447; H05K 1/02
USPC 174/258; 524/232; 522/78

(57) ABSTRACT

Inkjet printer-compatible solder mask inks include amide gellants to provide improved print resolution. A solder mask ink includes an amide gellant and a plurality of acrylate monomers, oligomers, or combinations thereof.

### BACKGROUND

Embodiments disclosed herein relate to solder masks employed in the manufacture of circuit boards. In particular, embodiments disclosed herein relate to inkjet printer-compatible solder mask inks comprising amide gellants that exhibit improved print resolution.

Printed circuit boards (PCBs) or printed wiring boards (PWBs) (hereinafter collectively PCB's) are platforms that connect and interface electronic components with each other and with other elements in computers, communication devices, consumer electronics, automated manufacturing and inspection equipment. PCB's may be produced from a base substrate, typically an insulating material, on which a thin copper layer is laminated or plated. Chemical etching is then used to remove areas of the copper to produce electrically conducting paths or traces. The traces permit electrical interconnection of the components attached to the PCB.

An insulative material, referred to as a solder mask, is then applied over the copper conducting paths. Solder masks protect the conducting paths on the PCB from being coated with solder during soldering steps, while leaving uncovered only the conducting pads that need to be contacted with molten solder. The solder mask layer on simple PCBs may be produced using screen-printing or spin-casting techniques. However, more densely populated PCBs typically utilize lithographic techniques to form a patterned solder mask on the copper layer.

Lithographic techniques used to prepare solder masks can involve multi-step sequences that are material and energy-intensive. For example, the process usually involves film coating, lithography, wet etching and curing, as indicated in the flow diagram of FIG. 1. In such a process, the solder masks are often epoxy-based materials that are spin-coated or applied in an analog fashion, followed by subtractive etching. This can be a costly and wasteful method.

As an alternative to lithographic techniques, the flow diagram of FIG. 2 shows the simplicity of using inkjet printing methods to prepare solder masks. Such printing methods can address, in part, some of the challenges presented in the manufacture of medium and higher density solder dams in PCBs. While medium density solder dams may be accessed via lithographic or printing methods, both methods may be challenged by increasingly complex high density solder dams, as limits in registration accuracy may become problematic. For such high resolution circuitry, it would be beneficial to increase the resolution of the solder mask that can be achieved via inkjet printing.

### SUMMARY

According to embodiments illustrated herein, there are provided solder mask inks that may exhibit improved print resolution in inkjet printing of solder masks for complex circuit boards.

In some aspects, embodiments disclosed herein relate to solder mask inks comprising an amide gellant a plurality of acrylate monomers, oligomers, or combinations thereof, and an adhesion promoter to promote adhesion of the solder mask to a metal surface.

In some aspects, embodiments disclosed herein relate to printed circuit boards comprising a conductive pattern disposed on an insulating substrate, and a cured solder mask disposed on at least a portion of the conductive pattern, wherein the cured solder mask is formed from a solder mask ink comprising an amide gellant, and a plurality of acrylate monomers, oligomers, or combinations thereof.

In some aspects, embodiments disclosed herein relate to solder mask inks comprising an amide gellant and a plurality of acrylate monomers, oligomers, or combinations thereof, wherein when the solder mask ink is cured it is characterized by having one or more of (1) a conductivity less than about 10⁻¹⁰ Siemens per centimeter (S/cm), (2) a pencil hardness of at least 2H, (3) a breakdown voltage of at least 5×10⁴ V/cm, (4) no visual effect after 30 rubs with isopropanol or methyl ethyl ketone solvents, and (5) no pooling, bubbling, melting or curling at 150° C. for 30 minutes.

### BRIEF DESCRIPTION OF THE DRAWINGS

For a better understanding of the present embodiments, reference may be made to the accompanying figures.

FIG. 1 shows a flow diagram for a general lithographic solder mask preparation.

FIG. 2 shows a flow diagram for a general inkjet solder mask preparation.

FIG. 3 shows a photograph of a circuit board with a printed solder mask, in accordance with embodiments disclosed herein.

FIG. 4 shows a photograph of a copper sheet with a printed solder mask, in accordance with embodiments disclosed herein.

FIG. 5 shows a diagram of a bottom-up approach to the formation of copper islands on a printed solder mask disposed on a circuit board comprising a glass substrate and copper laminate sheet with the solder mask printed directly on the copper laminate sheet.

FIG. 6 shows a photograph of a device prepared according to the diagram of FIG. 5.

FIG. 7 shows a resistance trace of the device of FIG. 6.

FIG. 8 shows photographs of devices comprising solder masks that were subjected to thermal stability testing. The top panel shows a location on a device that was exposed to a solder drop. The bottom panel shows the a location on a device that was exposed to the tip of a solder iron.

FIG. 9 shows a photograph of circuit boards with printed prior art solder mask formulations (cf. FIG. 3).

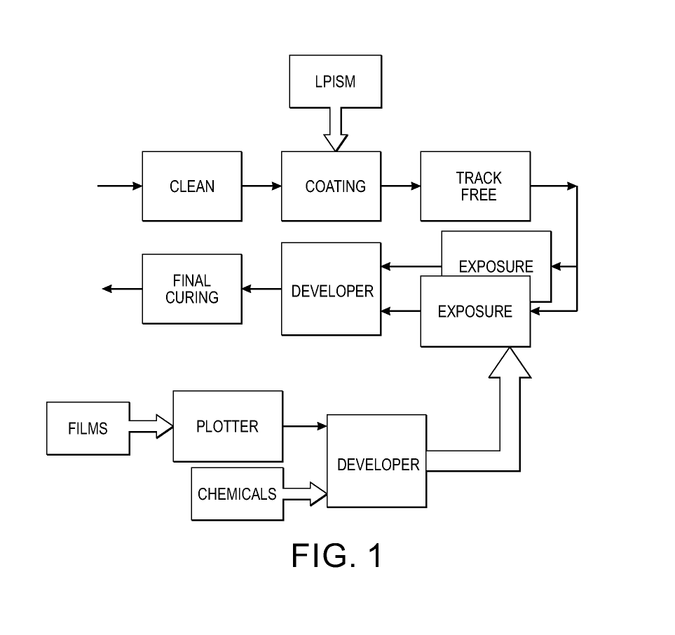

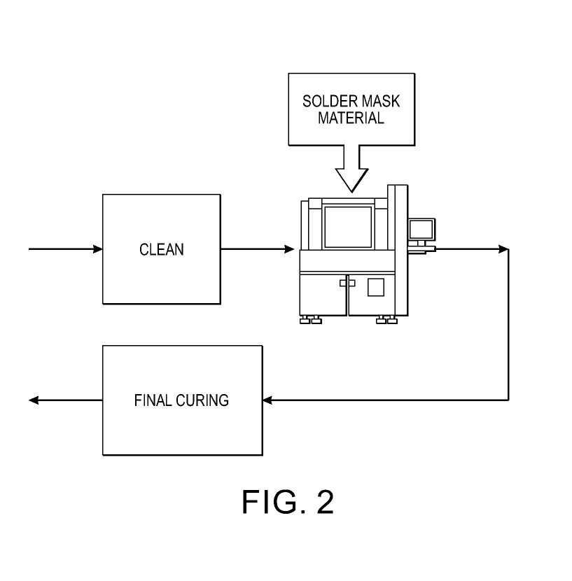

### DETAILED DESCRIPTION

In the following description, it is understood that other embodiments may be utilized and structural and operational changes may be made without departure from the scope of the present embodiments disclosed herein.

Embodiments disclosed herein are directed, in part, to solder mask inks comprising amide gellants for inkjet printing of solder masks on circuit boards and other substrates. In addition to reactive acrylate monomers, oligomers, and colorants, amide gellant materials have been added, providing printed solder mask films with improved aspect ratio and film integrity. The solder mask inks disclosed herein may exhibit improved performance over conventional inkjet printable UV curable solder mask formulations which contain no gellant. Moreover, the exemplary solder mask inks disclosed herein, in accordance with various embodiments, have passed the requisite tests for thermal stability and electrical resistance.

In some embodiments, there are provided solder mask inks comprising amide gellants and a plurality of acrylate monomers, oligomers, or combinations thereof. In some such embodiments, the amide gellant comprises a diamine condensed with a fatty acid dimer. Suitable diamines used in the preparation of the amide gellant include, without limitation, alkyl diamines, cycloalkyl diamines, alkylcycloalkyl diamines, aralkyl diamines, aryl diamines, and alkaryl diamines. Exemplary alkyl diamines include, without limitation, 1,2-diaminoethane (1,2-ethylene diamine, EDA), 1,2-diaminopropane, 1,3-diaminopropane, 1,2-diaminobutane, 1,3-diaminobutane, 1,4-diaminobutane, 1,2-diaminopentane, 1,3-diaminopentane, 1,4-diaminopentane, 1,5-diaminopentane, 1,6-hexanediamine, and similar higher diaminoalkanes. Cycloalkyl and alkyl cycloakyl diamines may include, without limitation, aminomethylcyclo-pentylamine and 1,2-cyclopentanediamine. Other diamines may include, without limitation, 1,2-diaminobenzene, lysine (or other diamine amino acids), 1,2-diaminobenzene, 1,4-diamine benzene, 1,2-diphenyl-1,2-ethane diamine, phenylene diamine, 2-hydroxypropylene diamine, hydantoin, N,N-bis(dihydroxyethyl)ethylenediamine, hexahydrotriazine, aminoethylpiperazine (AEP) or the like, or mixtures or combinations thereof. In some embodiments, the diamine comprises 1,2-ethylene diamine.

In some embodiments, suitable diamines can also include, without limitation, diamines of the general formula H₂N—R—NH₂ where R comprises linear or branched alkenyl groups having from about 1 and about 20 carbon atoms, cycloalkenyl groups having from about 1 and about 20 carbon atoms, alkylcycloalkenyl groups having from about 1 and about 20 carbon atoms, aralkenyl group having from about 1 and about 20 carbon atoms, or mixtures or combinations thereof. In some embodiments, alkenyl groups may have from about 1 to about 10 carbon atoms. In some embodiments, alkenyl groups can have from about 1 to about 6 carbon atoms. The R group can also include atoms other than carbon and hydrogen such as oxygen, nitrogen, fluorine and/or chlorine.

Fatty acid dimers suitable for use in the formation of amide gellants include the Pripol line of fatty acid dimers available from Croda Inc. (Edison, N.J.) or Uniqema Americas (Paterson, N.J.). The dimer fatty acids are generally prepared from predominantly C18 unsaturated fatty acid mixtures in a dimerization reaction that generates mixtures of monomer, dimers, and trimers. These reagents are available in a variety of degrees of purity from Uniqema as PRIPOL 1017, PRIPOL 1022, PRIPOL 1015, PRIPOL 1013, PRIPOL 1006, PRIPOL 1098, and PRIPOL 1009. High purity reagents PRIPOL 1098 and PRIPOL 1009 are particularly valued for their clarity where such considerations may be important. The Pripol dimers generally comprise a mixture of structures that include acyclic, carbocyclic, and aromatic ring structures that form under the dimerization reaction conditions.

The amide gellant compounds of the present embodiments can be prepared in a simple thermal condensation reaction as exemplified below in Scheme I.

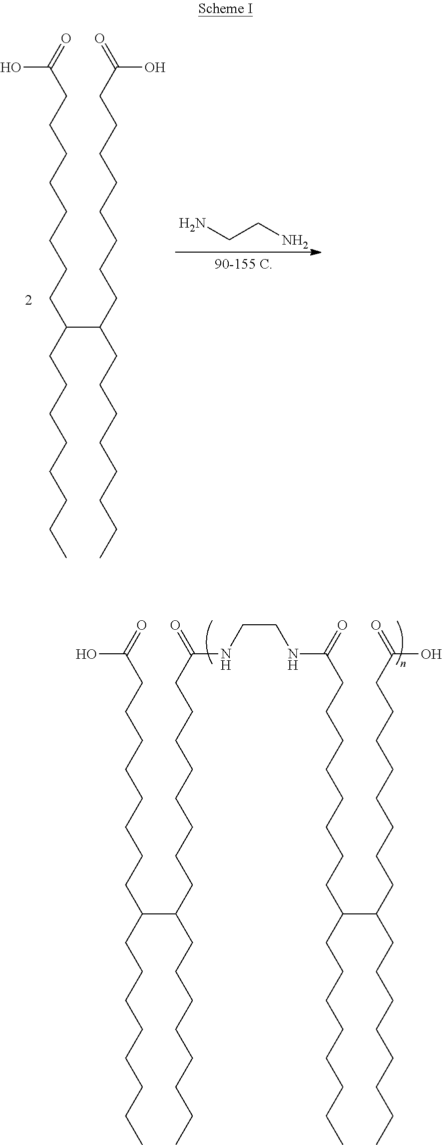

where n is an integer that may be altered according to the stoichiometry of the reaction. One skilled in the art will appreciate that the Pripol structure shown in Scheme I is simplified to demonstrate the condensation chemistry with an exemplary diamine, and should not therefore be limiting. As described above, the dimer structures present in Pripol products may comprise dimers having further carbocyclic and aromatic rings. In some embodiments, n may be in a range of from about 0 to about 20, about 0 to about 15, or about 0 to about 10, including any sub-ranges in between.

By controlling the amount of EDA, for example, the molecular weight distribution of the resultant amide gellant can be shifted to impart desirable physical characteristics to the amide gellant product. Typically, the amount of EDA relative to the amount of Pripol is expressed as an EDA:Pripol mole ratio. In embodiments, the EDA:Pripol ratio used in synthesizing the amide gellant may be in a range of from about 0.5:2.0 to about 1.5:2.0, or about 0.75:2 to about 1.5:2.0, or about 1.0:2 to about 1.5:2. In some embodiments, the EDA:Pripol ratio is about 0.75:2. In other embodiments, the EDA:Pripol ratio is about 1.0:2 or about 1.5:2, including any ratio in between. In some embodiments, the amide gellant comprises a molecular weight in a range of from about 2,000 daltons to about 4,500 daltons, about 2,500 daltons to about 4,000 daltons, or about 3,000 to about 3,500 daltons, including any sub-ranges in between. EDA:Pripol ratios below about 1.0:2.0 may provide a product with lower molecular weight and with a rubber-like property, while EDA:Pripol ratios greater than about 1.5:2.0 may provide a product with higher molecular weight which is relatively rigid.

In some embodiments, the amide gellant comprises an amount in a range of from about 0.1 to about 10 weight percent of the solder mask, or about 0.5 to about 5 weight percent of the solder mask, or about 0.75 to about 2 weight percent of the solder mask. In some embodiments, the amide gellant comprises about 1 weight percent of the solder mask ink.

Solder mask inks disclosed herein further comprise a plurality of acrylate monomers, oligomers, or combinations thereof. Suitable acrylate monomers are those which are commercially available under the SARTOMER™, ACTILANE™ and PHOTOMER™ trademarks such as SARTOMER™ 506 (isobornyl acrylate), SARTOMER™ 306 (tripropylene glycol diacrylate), ACTILANE™ 430 (trimethylol propane ethoxylate triacrylate), ACTILANE™ 251 (a tri-functional acrylate oligomer), ACTILANE™ 411 (a CTF acrylate), PHOTOMER™ 4072 (trimethylol propane propoxylate triacrylate), PHOTOMER™ 5429 (a polyester tetra acrylate) and PHOTOMER™ 4039 (a phenol ethoxylate monoacrylate). SARTOMERT™, ACTILANE™ and PHOTOMER™ are trademarks of Cray Valley Inc, Akros BV and Cognis Inc, respectively. Other examples of monomers are lauryl acrylate, isodecylacrylate, isooctyl acrylate, butyl acrylate, 2-hydroxy ethyl acrylate, 2-hydroxy propylacrylate, 2-ethyl hexyl acrylate, 1,6-hexanediol diacrylate, neopentyl glycol diacrylate, diethylene glycol diacrylate, butanediol diacrylate, trimethylolpropane triacrylate, pentaerythritol triacrylate, 1,3-butylene glycol diacrylate, 1,4-butylene glycol diacrylate, triethylene glycol diacrylate, pentaerythritol tetra acrylate, tripropylene glycol diacrylate, isobornyl acrylate, 2-norbornyl acrylate, cyclohexyl acrylate, phenoxyethyl acrylate and tetrahydrofurfuryl acrylate.

The amount of the plurality of acrylate monomers, oligomers, or combinations thereof in the solder mask inks disclosed herein may be in range of from about 50 percent by weight to about 97 percent by weight of the solder mask ink, including any value in between or fractions thereof. In other embodiments, the amount of the plurality of acrylate monomers, oligomers, or combinations thereof in the solder mask inks disclosed herein may be in range of from about 75 percent by weight to about 95 percent by weight of the solder mask ink, including any value in between or fractions thereof. In still other embodiments, the amount of the plurality of acrylate monomers, oligomers, or combinations thereof in the solder mask inks disclosed herein may be in range of from about 80 percent by weight to about 90 percent by weight of the solder mask ink, including any value in between or fractions thereof.

In some embodiments, solder mask inks disclosed herein may further comprise a photoinitiator. The photoinitiator may be selected from the group consisting of alpha-hydroxy ketones, mono-acyl phosphine oxides, bis-acyl phosphine oxides, and the like, and mixtures thereof. In specific embodiments, the solder mask inks disclosed herein can comprise any suitable photoinitiator. Examples of specific initiators include, but are not limited to, IRGACURE® 127, IRGACURE® 379, and IRGACURE® 819, all commercially available from BASF Chemicals, among others. Further examples of suitable initiators include (but are not limited to) benzophenones, benzophenone derivatives, benzyl ketones, α-alkoxy benzyl ketones, monomeric hydroxyl ketones, polymeric hydroxyl ketones, α-amino ketones, alkoxy ketones, acyl phosphine oxides, metallocenes, benzoin ethers, benzil ketals, α-hydroxyalkylphenones, α-aminoalkylphenones, acylphosphine photoinitiators sold under the trade designations of IRGACURE® and DAROCUR® from BASF, and the like. Specific examples include 1-hydroxy-cyclohexylphenylketone, benzophenone, 2-benzyl-2-(dimethylamino)-1-(4-(4-morphorlinyl)phenyl)-1-butanone, 2-methyl-1-(4-methylthio)phenyl-2-(4-morphorlinyl)-1-propanone, diphenyl-(2,4,6-trimethylbenzoyl) phosphine oxide, phenyl bis(2,4,6-trimethylbenzoyl) phosphine oxide, benzyl-dimethylketal, isopropylthioxanthone, 2,4,6-trimethylbenzoyldiphenylphosphine oxide (available as BASF LUCIRIN® TPO), 2,4,6-trimethylbenzoylethoxyphenylphosphine oxide (available as BASF LUCIRIN® TPO-L), bis(2,4,6-trimethylbenzoyl)-phenyl-phosphine oxide (available as BASF IRGACURE® 819) and other acyl phosphines, 2-methyl-1-(4-methylthio)phenyl-2-(4-morphorlinyl)-1-propanone (available as BASF IRGACURE® 907) and 1-(4-(2-hydroxyethoxy)phenyl)-2-hydroxy-2-methylpropan-1-one (available as BASF IRGACURE® 2959), 2-benzyl 2-dimethylamino1-(4-morpholinophenyl)butanone-1 (available as BASF IRGACURE® 369), 2-hydroxy-1-(4-(4-(2-hydroxy-2-methylpropionyl)-benzyl)-phenyl-2-methylpropan-1-one (available as BASF IRGACURE® 127), 2-dimethylamino-2-(4-methylbenzyl)-1-(4-morpholin-4-ylphenyl)-butanone (available as BASF IRGACURE® 379), titanocenes, isopropylthioxanthone, 1-hydroxy-cyclohexylphenylketone, benzophenone, 2,4,6-trimethylbenzophenone, 4-methylbenzophenone, diphenyl-(2,4,6-trimethylbenzoyl)phosphine oxide, 2,4,6-trimethylbenzoylphenylphosphinic acid ethyl ester, oligo(2-hydroxy-2-methyl-1-(4-(1-methylvinyl)phenyl)propanone), 2-hydroxy-2-methyl-1-phenyl-1-propanone, benzyl-dimethylketal, arylsulphonium slats, aryl iodonium salt, and the like, as well as mixtures thereof.

Optionally, the solder mask inks can also contain an amine synergist, which are co-initiators which can donate a hydrogen atom to a photoinitiator and thereby form a radical species that initiates polymerization, and can also consume dissolved oxygen, which inhibits free-radical polymerization, thereby increasing the speed of polymerization. Examples of suitable amine synergists include (but are not limited to) ethyl-4-dimethylaminobenzoate, 2-ethylhexyl-4-dimethylaminobenzoate, and the like, as well as mixtures thereof.

Initiators for solder mask inks disclosed herein can absorb radiation at any desired or effective wavelength, for example, from about 4 nanometers to about 560 nanometers, or from about 200 nanometers to about 560 nanometers, or from about 200 nanometers to about 420 nanometers, although the wavelength can be outside of these ranges.

Optionally, the photoinitiator may be present in the phase change ink in any desired or effective amount, for example from about 0.5 percent to about 15 percent by weight of the ink composition, or from about 1 percent to about 10 percent by weight of the ink composition, although the amount can be outside of these ranges.

In some embodiments, the solder mask inks disclosed herein may further comprise colorants. The ink compositions disclosed herein can thus be one with or without colorants. The solid ink may optionally contain colorants such as dyes or pigments. The colorants can be either from the cyan, magenta, yellow, black (CMYK) set or from spot colors obtained from custom color dyes or pigments or mixtures of pigments. Dye-based colorants are miscible with the ink base composition, which comprises the crystalline and amorphous components and any other additives.

In embodiments, the ink compositions described herein also include a colorant. Any desired or effective colorant can be employed in the phase change ink compositions, including dyes, pigments, mixtures thereof, and the like, provided that the colorant can be dissolved or dispersed in the ink carrier. Any dye or pigment may be chosen, provided that it is capable of being dispersed or dissolved in the ink carrier and is compatible with the other ink components. The phase change carrier compositions can be used in combination with conventional phase change ink colorant materials, such as Color Index (C.I.) Solvent Dyes, Disperse Dyes, modified Acid and Direct Dyes, Basic Dyes, Sulphur Dyes, Vat Dyes, and the like. Examples of suitable dyes include Neozapon Red 492 (BASF); Orasol Red G (Pylam Products); Direct Brilliant Pink B (Oriental Giant Dyes); Direct Red 3BL (Classic Dyestuffs); Supranol Brilliant Red 3BW (Bayer AG); Lemon Yellow 6G (United Chemie); Light Fast Yellow 3G (Shaanxi); Aizen Spilon Yellow C-GNH (Hodogaya Chemical); Bemachrome Yellow GD Sub (Classic Dyestuffs); Cartasol Brilliant Yellow 4GF (Clariant); Cibanone Yellow 2G (Classic Dyestuffs); Orasol Black RLI (BASF); Orasol Black CN (Pylam Products); Savinyl Black RLSN(Clariant); Pyrazol Black BG (Clariant); Morfast Black 101 (Rohm & Haas); Diaazol Black RN (ICI); Thermoplast Blue 670 (BASF); Orasol Blue GN (Pylam Products); Savinyl Blue GLS (Clariant); Luxol Fast Blue MBSN (Pylam Products); Sevron Blue 5GMF (Classic Dyestuffs); Basacid Blue 750 (BASF); Keyplast Blue (Keystone Aniline Corporation); Neozapon Black X51 (BASF); Classic Solvent Black 7 (Classic Dyestuffs); Sudan Blue 670 (C.I. 61554) (BASF); Sudan Yellow 146 (C.I. 12700) (BASF); Sudan Red 462 (C.I. 26050) (BASF); C.I. Disperse Yellow 238; Neptune Red Base NB543 (BASF, C.I. Solvent Red 49); Neopen Blue FF-4012 (BASF); Fatsol Black BR (C.I. Solvent Black 35) (Chemische Fabriek Triade BV); Morton Morplas Magenta 36 (C.I. Solvent Red 172); metal phthalocyanine colorants such as those disclosed in U.S. Pat. No. 6,221,137, the disclosure of which is totally incorporated herein by reference, and the like. Polymeric dyes can also be used, such as those disclosed in, for example, U.S. Pat. No. 5,621,022 and U.S. Pat. No. 5,231,135, the disclosures of each of which are herein entirely incorporated herein by reference, and commercially available from, for example, Milliken & Company as Milliken Ink Yellow 869, Milliken Ink Blue 92, Milliken Ink Red 357, Milliken Ink Yellow 1800, Milliken Ink Black 8915-67, uncut Reactint Orange X-38, uncut Reactint Blue X-17, Solvent Yellow 162, Acid Red 52, Solvent Blue 44, and uncut Reactint Violet X-80.

Pigments are also suitable colorants for the ink compositions disclosed herein. Examples of suitable pigments include PALIOGEN Violet 5100 (BASF); PALIOGEN Violet 5890 (BASF); HELIOGEN Green L8730 (BASF); LITHOL Scarlet D3700 (BASE); SUNFAST Blue 15:4 (Sun Chemical); Hostaperm Blue B2G-D (Clariant); Hostaperm Blue B4G (Clariant); Permanent Red P-F7RK; Hostaperm Violet BL (Clariant); LITHOL Scarlet 4440 (BASF); Bon Red C (Dominion Color Company); ORACET Pink RF (BASF); PALIOGEN Red 3871 K (BASF); SUNFAST Blue 15:3 (Sun Chemical); PALIOGEN Red 3340 (BASF); SUNFAST Carbazole Violet 23 (Sun Chemical); LITHOL Fast Scarlet L4300 (BASF); SUNBRITE Yellow 17 (Sun Chemical); HELIOGEN Blue L6900, L7020 (BASF); SUNBRITE Yellow 74 (Sun Chemical); SPECTRA PAC C Orange 16 (Sun Chemical); HELIOGEN Blue K6902, K6910 (BASF); SUNFAST Magenta 122 (Sun Chemical); HELIOGEN Blue D6840, D7080 (BASF); Sudan Blue OS (BASF); NEOPEN Blue FF4012 (BASF); PV Fast Blue B2GO1 (Clariant); IRGALITE Blue GLO (BASF); PALIOGEN Blue 6470 (BASF); Sudan Orange G (Aldrich); Sudan Orange 220 (BASF); PALIOGEN Orange 3040 (BASF); PALIOGEN Yellow 152, 1560 (BASF); LITHOL Fast Yellow 0991 K (BASF); PALIOTOL Yellow 1840 (BASF); NOVOPERM Yellow FGL (Clariant); Ink Jet Yellow 4G VP2532 (Clariant); Toner Yellow HG (Clariant); Lumogen Yellow D0790 (BASF); Suco-Yellow L1250 (BASF); Suco-Yellow D1355 (BASF); Suco Fast Yellow D1355, D1351 (BASF); HOSTAPERM Pink E 02 (Clariant); Hansa Brilliant Yellow 5GX03 (Clariant); Permanent Yellow GRL 02 (Clariant); Permanent Rubine L6B 05 (Clariant); FANAL Pink D4830 (BASF); CINQUASIA Magenta (DU PONT); PALIOGEN Black L0084 (BASF); Pigment Black K801 (BASF); and carbon blacks such as REGAL 330™ (Cabot), Nipex 150 (Evonik) Carbon Black 5250 and Carbon Black 5750 (Columbia Chemical), and the like, as well as mixtures thereof.

Pigment dispersions in the solder mask inks disclosed herein may be stabilized by synergists and dispersants. Generally, suitable pigments may be organic materials or inorganic. Magnetic material-based pigments are also suitable, for example, for the fabrication of robust Magnetic Ink Character Recognition (MICR) inks. Magnetic pigments include magnetic nanoparticles, such as for example, ferromagnetic nanoparticles.

Also suitable are the colorants disclosed in U.S. Pat. No. 6,472,523, U.S. Pat. No. 6,726,755, U.S. Pat. No. 6,476,219, U.S. Pat. No. 6,576,747, U.S. Pat. No. 6,713,614, U.S. Pat. No. 6,663,703, U.S. Pat. No. 6,755,902, U.S. Pat. No. 6,590,082, U.S. Pat. No. 6,696,552, U.S. Pat. No. 6,576,748, U.S. Pat. No. 6,646,111, U.S. Pat. No. 6,673,139, U.S. Pat. No. 6,958,406, U.S. Pat. No. 6,821,327, U.S. Pat. No. 7,053,227, U.S. Pat. No. 7,381,831 and U.S. Pat. No. 7,427,323, the disclosures of each of which are incorporated herein by reference in their entirety.

In some embodiments, solvent dyes may be employed. An example of a solvent dye suitable for use herein may include spirit soluble dyes because of their compatibility with the ink carriers disclosed herein. Examples of suitable spirit solvent dyes include Neozapon Red 492 (BASF); Orasol Red G (Pylam Products); Direct Brilliant Pink B (Global Colors); Aizen Spilon Red C-BH (Hodogaya Chemical); Kayanol Red 3BL (Nippon Kayaku); Spirit Fast Yellow 3G; Aizen Spilon Yellow C-GNH (Hodogaya Chemical); Cartasol Brilliant Yellow 4GF (Clariant); Pergasol Yellow 5RA EX (Classic Dyestuffs); Orasol Black RLI (BASF); Orasol Blue GN (Pylam Products); Savinyl Black RLS (Clariant); Morfast Black 101 (Rohm and Haas); Thermoplast Blue 670 (BASF); Savinyl Blue GLS (Sandoz); Luxol Fast Blue MBSN (Pylam); Sevron Blue 5GMF (Classic Dyestuffs); Basacid Blue 750 (BASF); Keyplast Blue (Keystone Aniline Corporation); Neozapon Black X51 (C.I. Solvent Black, C.I. 12195) (BASF); Sudan Blue 670 (C.I. 61554) (BASF); Sudan Yellow 146 (C.I. 12700) (BASF); Sudan Red 462 (C.I. 260501) (BASF), mixtures thereof and the like.

The colorant may be present in the phase change ink in any desired or effective amount to obtain the desired color or hue such as, for example, at least from about 0.1 percent by weight of the ink to about 50 percent by weight of the ink, at least from about 0.2 percent by weight of the ink to about 20 percent by weight of the ink, and at least from about 0.5 percent by weight of the ink to about 10 percent by weight of the ink.

In some embodiments, solder mask ink compositions comprising amide gellants and a plurality of acrylate monomers, oligomers, or combinations thereof, when cured may exhibit a conductivity less than about 10⁻¹⁰ Siemens per centimeter (S/cm), including less than about 10⁻¹¹ S/cm, or less than about 10⁻¹² S/cm.

In some embodiments, solder mask ink compositions comprising amide gellants and a plurality of acrylate monomers, oligomers, or combinations thereof, when cured may exhibit an thickness from about 2 micrometers to about 50 micrometers, including from about 5 micrometers to about 30 micrometers, or from about 10 micrometers to about 25 micrometers. When printed as a fine features such as a dot or a fine lines, the printed feature may have an aspect ratio in a range of from about 0.1 to about 2.0, including 0.2 to about 1.0. The registration accuracy of the printed solder mask is in a range of from about 2 micrometers to about 100 micrometers, including from about 5 micrometers to about 50 micrometers, or from about 5 micrometers to about 25 micrometers.

In some embodiments, solder mask ink compositions comprising amide gellants and a plurality of acrylate monomers, oligomers, or combinations thereof, when cured may exhibit a film integrity, as measured by the industrial standard set forth in IPC-SM-840C and its amendment. Some non-limiting exemplary properties include pencil hardness, dimensional stability, adhesion, chemical resistance, flammability, solderability.

Pencil Hardness:

This test is designed to evaluate the hardness of the solder mask surface and its resistance to abrasion. The test is carried out on three IPC-B-25A boards coated with solder mask and cured according to the manufacture's specified application and curing requirements. The board is placed on a firm horizontal surface. The hardest pencil (Eagle Turquoise brand ranging from 6H to 4B) is selected and is held firmly against the solder mask at a 45 degree angle. The pencil is then pushed away from the operator with uniform downward and forward pressure in a ¼ inch stroke. If the solder mask is cut or gouged then the next softest pencil is used until one is found which will not cut into the mask. The pencil hardness is then recorded which did not cut or gouge the solder mask.

Adhesion (Rigid):

The adhesion test determines the adhesion of solder mask used over melting metals, non-melting metals, and printed circuit board substrates. The adhesion test is performed on three checkerboard patterns, identified as coupon B on the IPC-B-25A board. The specimens are tested in as received and after the soldering process in accordance with J-STD-003. The solder mask is completely coated and cured according to the manufacture's specified application and curing requirements. The board is placed on a firm horizontal surface and a strip of pressure sensitive tape (3M brand 600) ½ “wide by 2” long is pressed firmly against the checkerboard pattern. All air bubbles are removed and the tape completely covers the coupon area. The tape is then rapidly removed in a 90° angle to the board. An unused strip of tape is used for each tape test. The tape is removed in less than one minute following application of the tape to the test pattern. The same procedure is followed after the board has been subjected to molten solder maintained at 473°±9° F. for five seconds. The tapes are then examined for evidence of film particles, separation, fracturing, or delamination of the coating from the surfaces of the bare material and conductors.

Resistance to Solvents and Cleaning Agents:

The resistance to solvent and cleaning agents is designed to ensure that the solder mask will not degrade when exposed to the most frequently industry used solvents/cleaning agents of the manufacturing process.

Embodiments disclosed herein also provide, in part, printed circuit boards comprising conductive patterns disposed on an insulating substrate and a cured solder mask disposed on at least a portion of the conductive pattern, wherein the cured solder mask is formed from a solder mask ink comprising the amide gellant described herein above, and a plurality of acrylate monomers, oligomers, or combinations thereof.

Printed circuit boards may be manufactured by conventional techniques and may include glass as the insulating substrate over which a copper laminate sheet is disposed, as shown in FIG. 5. In some embodiments, the insulating substrate may comprise a rigid or flexible structure. In some embodiments, the insulating substrate is one selected from a glass or a plastic resin.

In some embodiments, the conductive pattern may be formed directly on the insulating substrate. In other embodiments, a solder mask may be disposed on the copper laminate sheet and the conductive pattern formed on top of the solder mask. In some embodiments, a conductive pattern may be disposed on one or both sides of an insulating substrate and in either case a solder mask may be disposed on one or both sides of the insulating substrate.

In some embodiments, the conductive pattern of a printed circuit board may itself be provided by way of a conductive ink. In such embodiments, the conductive ink may be disposed directly on the insulating substrate obviating the need to etch a conductive copper-based pattern from a copper laminate sheet. Where conductive inks are employed, the conductive ink may be disposed on the substrate with the aid of an inkjet printer and subsequently, the solder mask may be printed over the conductive ink. Conductive inks generally comprise conductive particles dispersed in a carrier fluid. For example, silver nanoparticles and other organic-stabilized metal nanoparticles disclosed in U.S. Patent Application No. 2011/0305821, which is incorporated herein by reference in its entirety, may be employed in such conductive inks.

PCBs intended for challenging environments may further comprise a conformal coating which is applied by dipping or spraying after the components have been soldered. In some embodiments, such coatings may prevent, inter alia, corrosion and leakage currents or shorting due to condensation. In some embodiments, the conformal coating comprises at least one of a wax, a silicone rubber, a polyurethane, an acrylic resin, and an epoxy resin. PCBs may further be configured with protective antistatic agents.

Embodiments disclosed herein also provide, in part, methods of printing solder masks comprising incorporating a solder mask ink into an ink jet printing apparatus, the solder mask ink comprising an amide gellant, and a plurality of acrylate monomers, oligomers, or combinations thereof; causing droplets of melted solder mask ink to be ejected onto a printed circuit board to form a patterned solder mask on the printed circuit board; and curing the patterned solder mask.

In some such embodiments the curing step may be catalyzed by one or more photoinitiators present in the solder mask ink. Thus, after printing of the solder mask ink, the patterned mask may be cured by exposure to light, such as UV light. In some embodiments, light curing may be performed with over a large spectrum of light including UV, IR, near-IR, and visible light.

In some embodiments, printing methods may include printing of a conductive pattern with a conductive ink prior to printing the solder mask. In some embodiments, printing solder masks may be performed substantially simultaneously with printing of the conductive pattern. This may be achieved, for example, with a tandem printhead with multiple resevoirs that could alternate between printing insulator and conductor on the same substrate.

The solder mask inks described herein are further illustrated in the following examples. All parts and percentages are by weight unless otherwise indicated.

It will be appreciated that various of the above-disclosed and other features and functions, or alternatives thereof, may be desirably combined into many other different systems or applications. Also, various presently unforeseen or unanticipated alternatives, modifications, variations or improvements therein may be subsequently made by those skilled in the art, and are also intended to be encompassed by the following claims.

While the description above refers to particular embodiments, it will be understood that many modifications may be made without departing from the spirit thereof. The accompanying claims are intended to cover such modifications as would fall within the true scope and spirit of embodiments herein.

The presently disclosed embodiments are, therefore, to be considered in all respects as illustrative and not restrictive, the scope of embodiments being indicated by the appended claims rather than the foregoing description. All changes that come within the meaning of and range of equivalency of the claims are intended to be embraced therein.

### EXAMPLES

The examples set forth herein below and are illustrative of different compositions and conditions that can be used in practicing the present embodiments. All proportions are by weight unless otherwise indicated. It will be apparent, however, that the present embodiments can be practiced with many types of compositions and can have many different uses in accordance with the disclosure above and as pointed out hereinafter.

### Example I

### Solder Mask Ink Formulations

This Example shows exemplary solder mask ink formulations, in accordance with embodiments disclosed herein.

Solder mask ink formulations 1-4 were prepared by mixing the components in a 30 mL amber glass bottle with a stir bar for 1 hour at 90° C. SR238, CN975, CN944 are available from Sartomer Company (Exton, Pa.). SILMER® ACR Di-10 is available from Siltech Corporation (Toronto, ON, CA). PHOTOMER® 5429 is available from IGM resins (Charlotte, N.C.). IRGACURE® photoinitators are available from BASF (Germany). Amide gellants were prepared with ethylenediamine available from Sigma-Aldrich Chemical Company (St. Louis, Mo.) and PRIPOL 1009, a dimer acid available from Croda Inc.

### Example I-A

### Preparation of the Amide Gellant Precursor (Baseline)

A baseline amide gellant precursor using a EDA:Pripol ratio of 1.125:2 was prepared as follows. To a 2 L stainless steel reactor equipped with baffles and 4-blade impeller was added Pripol 1009 dimer diacid (Cognis Corporation) (703.1 g, acid number=194 mg/g, 1215 mmol). The reactor was purged with argon and heated to 90° C., and the impeller was turned on to 400 RPM. Next, ethylenediamine (Huntsman Chemical Corporation, 21.9 g, 364 mmol) was slowly added through a feed line directly into the reactor over 15 minutes. The reactor temperature was set 95° C. Next, the reactor temperature was ramped up to 165° C. over 280 minutes, and held at 165° C. for 1 hour. Finally, the molten organoamide product was discharged into a foil pan and allowed to cool to room temperature. The product was an amber-coloured solid resin. Acid#: 133.7.

### Example I-B

### Preparation of the Amide Gellant (Baseline)

A baseline amide gellant precursor using a EDA:Pripol ratio of 1.125:2 was prepared as follows. To a 2 L stainless steel Buchi reactor equipped with 4-blade steel impeller, baffle, and condenser was added organoamide (711.8 g, acid number=133.7, 614.65 mmol) via the addition port, using a heat gun to melt the materials. Next, the reactor was purged with N₂ gasat 3 SCFH (standard cubic feet per hour) flow rate, and heated to 210° C., and mixing at 450 RPM was started. Next, 2-phenoxyethanol (281.2 g, 2035.4 mmol, Aldrich Chemicals) and Fascat 4100 (0.70 g, 2.05 mmol, Arkema Inc.) were premixed in a beaker, and added to the reaction. The reaction port was closed, and the reaction was held at 210° C. for 2.5 hours. After 2.5 hours, the reactor port was opened, and 27.5 g more phenoxyethanol was added, and the reaction was allowed to run for 4 hours. After the reaction was completed, the molten gellant product was discharged into a foil pan and allowed to cool to room temperature. The produce was an amber-colored firm gel. Acid number=3.9.

### Ink Formulation 1

| Component | wt % | 20 m/g |
|---|---|---|
| SR238 (hexanediol diacrylate) | 74.5% | 14.90 |
| CN975 (ARUA) | 5.0% | 1 |
| Green pigment dispersion in SR238 | 3.0% | 0.6 |
| Silmer ACR Di-10 | 5.0% | 1 |
| Amide gellant 0.75:2 EDA:Pripol MEDIUM MW | 1.0% | 0.2 |
| Gellant | | |
| Photomer 5429 | 4.0% | 0.8 |
| Irgacure 379 | 3.0% | 0.6 |
| Irgacure 819 | 1.0% | 0.2 |
| Irgacure 127 | 3.5% | 0.70 |
| TOTAL | 100.0% | 20 |

### Ink Formulation 2

| Component | wt % | m/g |
|---|---|---|
| SR238 (available from Sartomer (Exton, PA)) | 74.5% | 14.90 |
| CN944 (ARUA polyether) | 5.0% | 1 |
| Green pigment dispersion in SR238 | 3.0% | 0.6 |
| Silmer ACR Di-10 | 5.0% | 1 |
| Amide gellant 0.75:2 EDA:Pripol MEDIUM MW | 1.0% | 0.2 |
| Gellant | | |
| Photomer 5429 | 4.0% | 0.8 |
| Irgacure 379 | 3.0% | 0.6 |
| Irgacure 819 | 1.0% | 0.2 |
| Irgacure 127 | 3.5% | 0.70 |
| TOTAL | 100.0% | 20 |

### Ink Formulation 3

| Component | wt % | m/g |
|---|---|---|
| SR238 | 75.3% | 15.06 |
| CN3100 (aliphatic UA/methacrylate AE) | 5.0% | 1 |
| Cyan pigment dispersion | 1.5% | 0.3 |
| Yellow pigment dispersion | 1.5% | 0.3 |
| Silmer ACR Di-10 | 2.0% | 0.4 |
| Amide gellant 0.75:2 EDA:Pripol MEDIUM MW | 2.0% | 0.4 |
| Gellant | | |
| Photomer 5429 | 5.0% | 1 |
| UV10 stabilizer | 0.2% | 0.04 |
| Irgacure 379 | 3.0% | 0.6 |
| Irgacure 819 | 1.0% | 0.2 |
| Irgacure 127 | 3.5% | 0.70 |
| TOTAL | 100.0% | 20 |

### Ink Formulation 4

| Component | wt % | m/g |
|---|---|---|
| SR238 | 74.5% | 14.90 |
| CN944 | 5.0% | 1 |
| Green pigment dispersion in SR238 | 3.0% | 0.6 |
| Silmer ACR Di-10 | 5.0% | 1 |
| Amide gellant 0.75:2 EDA:Pripol MEDIUM MW | 1.0% | 0.2 |
| Gellant | | |
| Photomer 5429 | 4.0% | 0.8 |
| Irgacure 379 | 3.0% | 0.6 |
| Irgacure 819 | 1.0% | 0.2 |
| Irgacure 127 | 3.5% | 0.70 |
| TOTAL | 100.0% | 20 |

### Example II

### Printing and Curing of Solder Mask

This Example shows the printing and curing of solder mask ink formulations 1-4 from Example 1 and characterization of the cured inks.

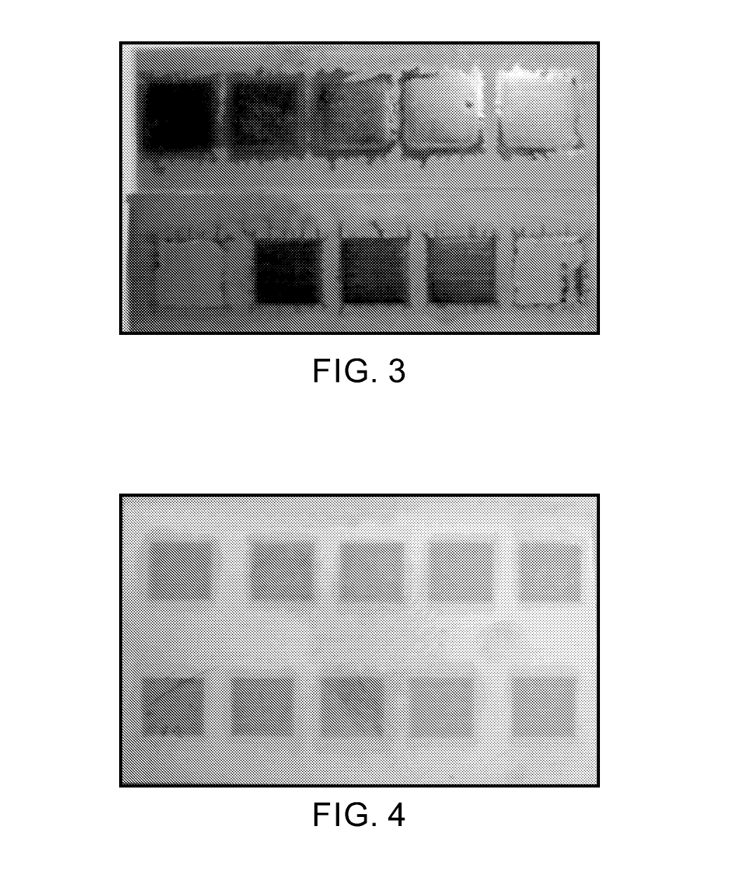

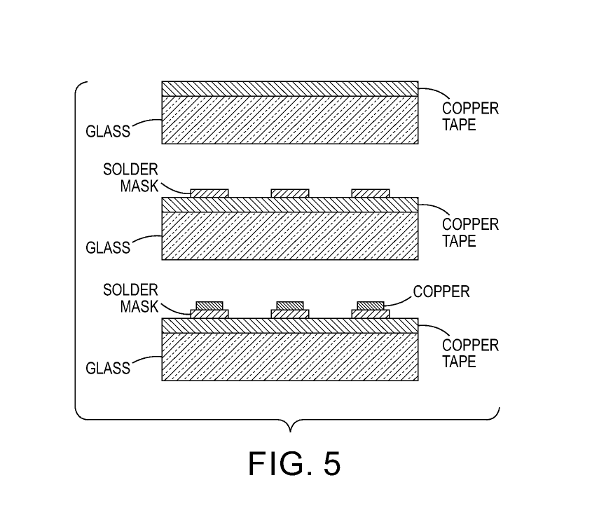

Inks were printed using a Dimatix printer (DMP-2800) equipped with a 10 pL cartridge. Printed samples were cured by passing under a Fusions UV Lighthammer lamp at 32 feet per minute. The cured samples were hard and did not smear under thumb twist pressures. Images of printed inks on PCB (printed circuit board) and copper coated PCB's are shown in FIGS. 3 and 4. FIG. 3 shows a photograph of a printed circuit board with printed Ink Formulation 3 in the top panel of five squares and Ink Formulation 4 in the bottom panel of five squares. FIG. 4 shows a photograph of a print onto copper laminate with printed Ink Formulation 1 in the top panel of five squares and Ink Formulation 2 in the bottom panel of five squares. Note the pigment is well dispersed and the squares demonstrate sharp edges.

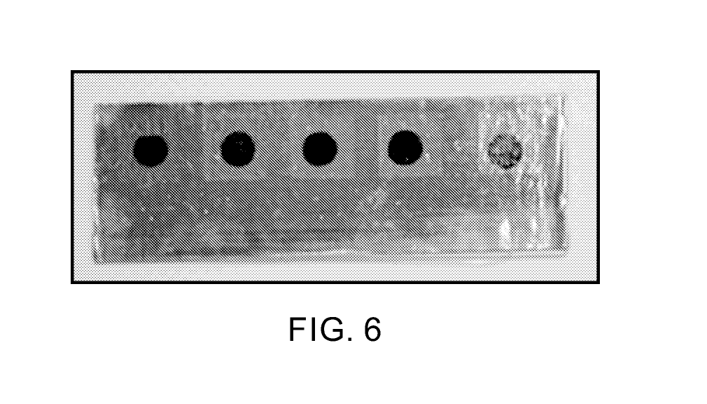

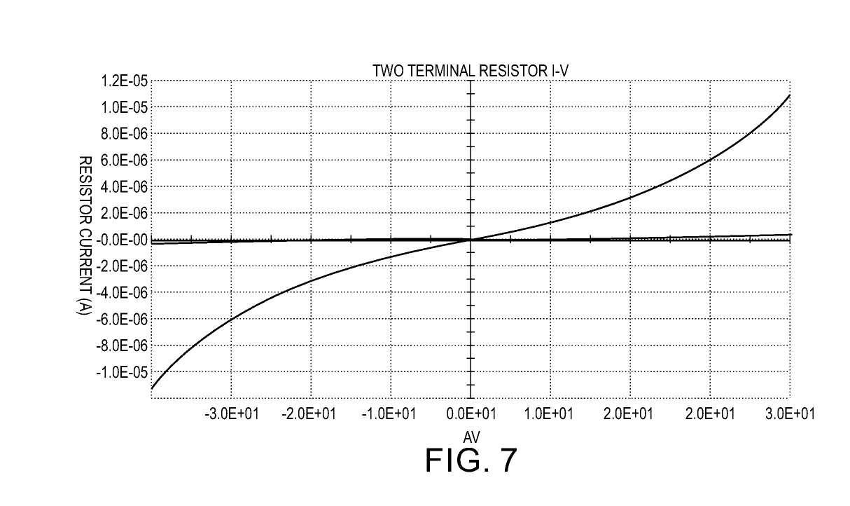

Electrical resistance was measured using a Keithley apparatus (SCS-4200) from −80V to +80V sweep. FIG. 5 shows a schematic showing the sandwich structure that was tested, with photograph of the printed pads of an actual five point sample having this structure in FIG. 6. A trace of the resistance measurement is shown in FIG. 7. The flat line passing through the origin is indicative of a resistive film (no conductivity). The sine wave curve is a defect that arises from a printed defect.

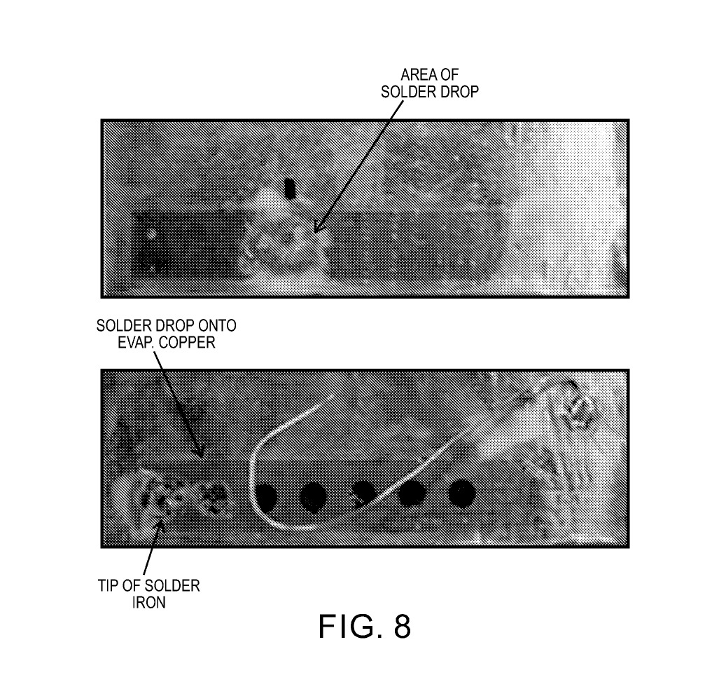

The printed samples were subjected to thermal stability by placing the printed structure/PCB into an oven at 300° C. for five minutes. No evidence of film degradation was observed as shown in the top panel of the photograph of FIG. 8. The printed samples were subjected to a drop of molten solder. There was no evidence of dielectric breakdown, and the printed film remained intact, as indicated in the bottom panel of the photograph of FIG. 8. Printed pads were deposited onto the solder mask, and the solder adhered to the copper pad, but not the solder mask, another indication that the printed solder mask was a functional mask.

A number of properties were measured on Ink Formulations 1-4 and the results of these tests are summarized in Table 1 below.

TABLE 1

| | | |
|---|---|---|
| Adhesion | Tape test (Permacel) | No removal |
| Continuity | Dielectric Test | No pinholes, shorts |
| Electrical | Ohmmeter/breakdown | No breakdown after 100 V |
| Resistance | test | applied |
| Edge Acuity | Profilometry | Significant barrier |
| Abrasion | Pencil hardness/scratch | 4H+/scratched, but no |
| Resistance | test | removal |
| Thermal | Oven burst/solder drop | No melting, peeling |
| Resistance | test | |
| Solvent Resistance | IPA/MEK rub test | No removal after 30 rubs |

Adhesion (Rigid):

The adhesion test determines the adhesion of solder mask used over melting metals, non-melting metals, and printed circuit board substrates. The adhesion test is performed on three checkerboard patterns, identified as coupon B on the IPC-B-25A board. The specimens are tested in as received and after the soldering process in accordance with J-STD-003. The solder mask is completely coated and cured according to the manufacture's specified application and curing requirements. The board is placed on a firm horizontal surface and a strip of pressure sensitive tape (3M brand 600) ½ “wide by 2” long is pressed firmly against the checkerboard pattern. All air bubbles are removed and the tape completely cover the coupon area. The tape is then rapidly removed in a 90° angle to the board. An unused strip of tape is used for each tape test. The tape is removed in less than one minute following application of the tape to the test pattern. The same procedure is followed after the board has been subjected to molten solder maintained at 473°±9° F. for five seconds. The tapes are then examined for evidence of film particles, separation, fracturing, or delamination of the coating from the surfaces of the bare material and conductors.

Continuity/Electrical Resistance:

Referring to FIG. 5, copper tape was applied to a glass slide, and wiped with isopropanol (IPA) to prevent contamination. Solder mask was jetted (Dimatix printer) onto the copper surface. Copper was evaporated onto the solder mask via a metal evaporator. Shorting was lightly tested by using an ohmmeter. Dielectric breakdown was then tested using the semiconductor characterization system, to measure the current necessary for the ink breakdown.

Edge Acuity:

A thickness of about 20 microns was established to provide a sufficient barrier for the purposes of edge acuity. In order to increase the thickness of the solder mask, multiple layers of solder mask could be printed before curing, and then tested for thickness. A thickness of about 9.7 microns could be established for one layer, about 24.2 for two layers, and about 26.1 for three layers. An ideal thickness is thus reached at around 2-3 printed layers.

Abrasion Resistance-Pencil Hardness:

This test is designed to evaluate the hardness of the solder mask surface and its resistance to abrasion. The test is carried out on three IPC-B-25A boards coated with solder mask and cured according to the manufacture's specified application and curing requirements. The board is placed on a firm horizontal surface. The hardest pencil (Eagle Turquoise brand ranging from 6H to 4B) is selected and is held firmly against the solder mask at a 45 degree angle. The pencil is then pushed away from the operator with uniform downward and forward pressure in a ¼ inch stroke. If the solder mask is cut or gouged then the next softest pencil is used until one is found which will not cut into the mask. The pencil hardness is then recorded which did not cut or gouge the solder mask.

Thermal Resistance:

Two tests were used in the assessment of thermal resistance: oven burst and solder drop. An oven burst test evaluates the overall stability of the mask on the substrate when subjected to high temperature over a short period of time (similar to overheating). The mask is expected to withstand the temperature without suffering damage. It was shown that the masks from Formulations 1-4 were capable of withstanding a temperature of 300° C. for about 5 minutes. A solder drop tests simulated the ability of the mask to withstand heat when applied to specific points. Hot solder typically has temperatures of 200 to 300° C., while the tip of the solder iron itself has temperatures of about 500 to 600° C. FIG. 8 shows the testing that was performed to determine if the solder drop has any damage to the performance of the solder mask. While there appears to be some oxidation and minor surface damage, the film integrity was unchanged and had no effects on performance. However, when the tip of the solder iron was applied, it melted through the mask as indicated in the lower panel of FIG. 8.

Solvent Resistance:

Isopropanol/Methyl Ethyl Ketone (IPA/MEK) were employed in a rub test to determine resistance to solvents. After 30 rubs there was no visual removal of the cured solder mask materials.

### Example III

This Example shows a comparison of the performance of prior art inks lacking the amide gellant disclosed herein.

As a control experiment, a solder mask ink formulations in the prior art were prepared by closely following Examples 48 and 55 of U.S. Patent Application No. 2006/0047014.

### Ink Formulation of Example 48

| Component | wt % | m/g |
|---|---|---|
| SR506 | 54.8% | 10.96 |
| SR306 (tripropylene glycol diacrylate) | 29.2% | 5.84 |
| Photomer 5429 | 4.9% | 0.98 |
| Silmer ACR Di-10 | 0.4% | 0.08 |
| green pigment dispersion in SR238 | 3.0% | 0.6 |
| UV10 stabilizer | 0.2% | 0.04 |
| Irgacure 379 | 3.0% | 0.6 |
| Irgacure 819 | 1.0% | 0.2 |
| Irgacure 127 | 3.5% | 0.70 |
| TOTAL | 100.0% | 20 |

### Ink Formulation of Example 55

| Component | wt % | 20 m/g |
|---|---|---|
| SR506 | 63.8% | 12.76 |
| SR306 (tripropylene glycol diacrylate) | 13.8% | 2.76 |
| SR499 (ethoxylate (6) trimethylolpropyl triacrylate) | 3.2% | 0.64 |
| CN929 (trifunctional urethane acrylate) | 3.2% | 0.64 |
| Photomer 5429 | 4.9% | 0.98 |
| Silmer ACR Di-10 | 0.4% | 0.08 |
| green pigment dispersion in SR238 | 3.0% | 0.6 |
| UV10 stabilizer | 0.2% | 0.04 |
| Irgacure 379 | 3.0% | 0.6 |
| Irgacure 819 | 1.0% | 0.2 |
| Irgacure 127 | 3.5% | 0.70 |
| TOTAL | 100.0% | 20 |

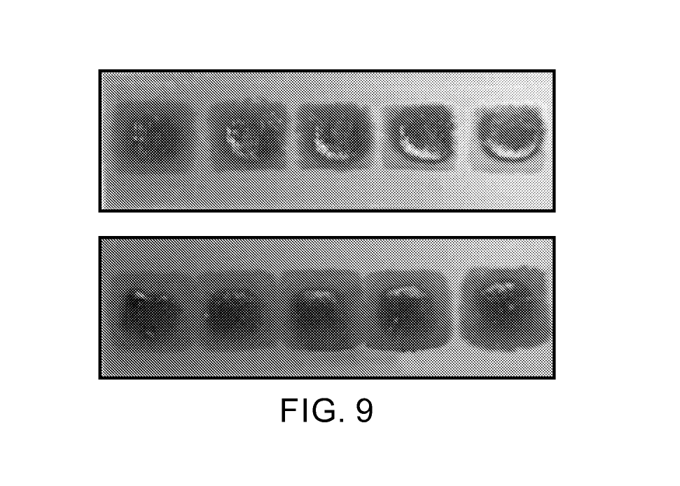

Images of the printed and cured films of Ink Formulations 48 and 55 are shown in FIG. 9, top and bottom panels, respectively. The poor wetting, and non-uniform pigment dispersions are indicative of solder mask films with poor film integrity, indicating that the solder mask formulations disclosed herein which include the amide gellant provide an improvement in film integrity.

The claims, as originally presented and as they may be amended, encompass variations, alternatives, modifications, improvements, equivalents, and substantial equivalents of the embodiments and teachings disclosed herein, including those that are presently unforeseen or unappreciated, and that, for example, may arise from applicants/patentees and others. Unless specifically recited in a claim, steps or components of claims should not be implied or imported from the specification or any other claims as to any particular order, number, position, size, shape, angle, color, or material.

All the patents and applications referred to herein are hereby specifically, and totally incorporated herein by reference in their entirety in the instant specification.

1. A solder mask ink comprising:
an amide gellant;
a plurality of acrylate monomers, oligomers, or combinations thereof; and
an adhesion promoter to promote adhesion of a solder mask formed by the solder mask ink to a metal surface, wherein the solder mask adheres to the metal surface, wherein when the solder mask ink is cured, the cured solder mask ink has a pencil hardness of 4H.

2. The solder mask ink of claim 1, wherein the amide gellant comprises a diamine condensed with a fatty acid dimer.

3. The solder mask ink of claim 2, wherein a ratio of diamine to fatty acid dimer is in a range of from about 1.0:2.0 to about 1.5:2.0.

4. The solder mask ink of claim 1, wherein the amide gellant comprises a molecular weight in a range of from about 2500 daltons to about 4000 daltons.

5. The solder mask ink of claim 1, wherein the amide gellant comprises an amount of from about 0.5 weight percent to about 5 weight percent of the solder mask ink.

6. The solder mask ink of claim 1, further comprising a photo initiator.

7. The solder mask ink of claim 1, further comprising a colorant.

8. (canceled)

9. (canceled)

10. (canceled)

11. (canceled)

12. (canceled)

13. (canceled)

14. (canceled)

15. (canceled)

16. (canceled)

17. (canceled)

18. (canceled)
